(19) United States
(12) Patent Application Publication
(10) Pub. No.: US 2013/0009272 A1
(43) Pub. Date: Jan. 10, 2013

(54) Semiconductor device

(75) Inventors: Shinya SAKURAI, Obu-city (JP); Akira Yamada, Nukata-gun (JP)

(73) Assignee: DENSO CORPORATION, Kariya-city (JP)

(21) Appl. No.: 13/534,278

(22) Filed: Jun. 27, 2012

(30) Foreign Application Priority Data
Jul. 5, 2011 (JP) 2011-149211
Apr. 11, 2012 (JP) 2012-90391

(51) Int. Cl. H01L 27/07

(52) U.S. Cl. 257/496; 257/E27.025

(57) ABSTRACT

A semiconductor device includes a semiconductor substrate, a semiconductor element disposed in the semiconductor substrate, a guard ring surrounding at least a part of a periphery of the semiconductor element, a guard ring terminal coupled with the guard ring, a power supply line divided from a line coupled with a power source and applying a first constant voltage to the semiconductor element based on a voltage generated by the power source, a guard ring terminal fixation line divided from the line coupled with the power source and applying a second constant voltage to the guard ring terminal, a bypass capacitor disposed on the guard ring terminal fixation line so as to be coupled in parallel with the guard ring, and a resistor disposed on the guard ring terminal fixation line between the power source and the bypass capacitor.

### CROSS REFERENCE TO RELATED APPLICATIONS

The present application is based on and claims priority to Japanese Patent Applications No. 2011-149211 filed on Jul. 5, 2011 and No. 2012-90391 filed on Apr. 11, 2012, the contents of which are incorporated in their entirety herein by reference.

### TECHNICAL FIELD

The present disclosure relates to a semiconductor device.

### BACKGROUND

A semiconductor device in which a low potential reference circuit and a high potential reference circuit are disposed in an active layer in a silicon-on-insulator (SOI) substrate, which includes a buried insulating layer, is disclosed, for example, in JP-A-2006-093229 and JP-A-2009-147119 (corresponding to US 2009/0152668 A). The semiconductor device can be used, for example, as an element in an inverter control apparatus that drives a load, such as a motor.

### SUMMARY

It is an object of the present disclosure to provide a semiconductor device that can restrict an inflow of a displacement current to an element region and thereby restricting a malfunction of a circuit.

A semiconductor device according to a first aspect of the present disclosure includes a semiconductor substrate, a semiconductor element, a guard ring, a guard ring terminal, a power supply line, a guard ring terminal fixation line, a bypass capacitor, and a resistor. The semiconductor element is disposed in the semiconductor substrate. The guard ring is disposed in the semiconductor substrate and surrounds at least a part of a periphery of the semiconductor element. The guard ring terminal is coupled with the guard ring. The power supply line is divided from a line coupled with a power source and applies a first constant voltage to the semiconductor element based on a voltage generated by the power source. The guard ring terminal fixation line is divided from the line coupled with the power source and applies a second constant voltage to the guard ring terminal. The bypass capacitor is disposed on the guard ring terminal fixation line so as to be coupled in parallel with the guard ring. The resistor is disposed on the guard ring terminal fixation line between the power source and the bypass capacitor.

The semiconductor device according to the first aspect can restrict a malfunction of a circuit by restricting an inflow of a displacement current, which charges and discharges a parasitic capacitance or a junction capacitance, to an element region. The semiconductor device can also restrict a malfunction of the circuit by an RC circuit when noises enter the power source. Furthermore, the bypass capacitor does not have to be a discrete component.

A semiconductor device according to a second aspect of the present disclosure includes a semiconductor substrate, a well, a dielectric isolation region, a semiconductor element, a guard ring, a guard ring terminal, a power supply line, a guard ring terminal fixation line, a resistor, and a bypass capacitor. The semiconductor substrate is formed of a silicon-on-insulator substrate including a support substrate, a buried oxide layer disposed on the support substrate, and a semiconductor layer of a second conductivity type disposed on the buried oxide layer. The well has a first conductivity type and is disposed in an element region in the semiconductor layer. The dielectric isolation region surrounds the element region. The semiconductor element is disposed in the well. The guard ring has a higher conductivity than the semiconductor layer and surrounds at least a part of a periphery of the well. The guard ring terminal is coupled with the guard ring. The power supply line is divided from a line coupled with a power source and applies a first constant voltage to the semiconductor element based on a voltage generated by the power source. The guard ring terminal fixation line is divided from the line coupled with the power source and applies a second constant voltage to the guard ring terminal. The resistor and the bypass capacitor are disposed on the guard ring terminal fixation line. A potential of the guard ring terminal is fixed to a potential between the resistor and the bypass capacitor.

The semiconductor device according to the second aspect can restrict a malfunction of a circuit by restricting an inflow of a displacement current, which charges and discharges a parasitic capacitance or a junction capacitance, to the element region. The semiconductor device can also restrict a malfunction of the circuit by an RC circuit when noises enter the power source. Furthermore, the bypass capacitor does not have to be a discrete component.

A semiconductor device according to a third aspect of the present disclosure includes a semiconductor substrate, a well, a semiconductor element, a guard ring, a guard ring terminal, a power supply line, a guard ring terminal fixation line, a resistor, and a bypass capacitor. The semiconductor substrate includes a substrate of a first conductivity type and a second layer of a second conductivity type disposed on the substrate. The well has the first conductivity type and is disposed in the semiconductor layer. The semiconductor element is disposed in the well. The guard ring has a higher conductivity than the semiconductor layer and surrounds at least a part of a periphery of the well. The guard ring terminal is coupled with the guard ring. The power supply line is divided from a line coupled with a power source and applies a first constant voltage to the semiconductor element based on a voltage generated by the power source. The guard ring terminal fixation line is divided from the line coupled with the power source and applies a second constant voltage to the guard ring terminal. The resistor and the bypass capacitor are disposed on the guard ring terminal fixation line. A potential of the guard ring terminal is fixed to a potential between the resistor and the bypass capacitor.

The semiconductor device according to the third aspect can restrict a malfunction of a circuit by restricting an inflow of a displacement current, which charges and discharges a parasitic capacitance or a junction capacitance, to an element region. The semiconductor device can also restrict a malfunction of the circuit by an RC circuit when noises enter the power source. Furthermore, the bypass capacitor does not have to be a discrete component.

### BRIEF DESCRIPTION OF THE DRAWINGS

Additional objects and advantages of the present disclosure will be more readily apparent from the following detailed description when taken together with the accompanying drawings. In the drawings:

FIG. 1 is a diagram showing an upper layout of a semiconductor device according to a first embodiment of the present disclosure;

FIG. 2A is a cross-sectional view of the semiconductor device taken along line IIA-IIA in FIG. 1, FIG. 2B is a cross-sectional view of the semiconductor device taken along line IIB-IIB in FIG. 1, and FIG. 2C is a cross-sectional view of the semiconductor device taken along line IIC-IIC in FIG. 1;

FIG. 3A is a diagram showing an upper layout of a high voltage MOSFET, FIG. 3B is a diagram showing an upper layout of a p-channel type MOSFET, and FIG. 3C is a diagram showing an upper layout of a capacitor;

FIG. 4 is a diagram showing a circuit configuration of a p-channel type MOSFET;

FIG. 5 is a diagram showing an example of a coupling configuration of the p-channel type MOSFET;

FIG. 6A is a diagram showing a circuit configuration of a p-channel type MOSFET according to a second embodiment of the present disclosure, and FIG. 6B is a diagram showing an upper layout of the p-channel type MOSFET shown in FIG. 6A;

FIG. 7A is a diagram showing a circuit configuration of a p-channel type MOSFET according to a modification of the second embodiment, and FIG. 7B is a diagram showing an upper layout of the p-channel type MOSFET shown in FIG. 7A;

FIG. 8A is a diagram showing a circuit configuration of a p-channel type MOSFET according to a third embodiment of the present disclosure, and FIG. 8B is a diagram showing an upper layout of the p-channel type MOSFET shown in FIG. 8A;

FIG. 9A is a diagram showing a circuit configuration of a p-channel type MOSFET according to a fourth embodiment of the present disclosure, and FIG. 9B is a diagram showing an upper layout of the p-channel type MOSFET shown in FIG. 9A;

FIG. 10 is a diagram showing a circuit configuration of a p-channel type MOSFET according to another embodiment of the present disclosure;

FIG. 11 is a diagram showing a semiconductor device that includes an epitaxial substrate as a semiconductor substrate;

FIG. 12A is a diagram showing an upper layout of a p-channel type MOSFET according to another embodiment of the present disclosure, and FIG. 12B is a diagram showing an upper layout of a p-channel type MOSFET according to another embodiment of the present disclosure;

FIG. 13 is a diagram showing an inverter driving circuit including a high voltage integrated circuit according to a related art;

FIG. 14 is a cross-sectional view of a high voltage integrated circuit according to a related art in which a displacement current is generated; and

FIG. 15 is a diagram showing a p-channel type MOSFET including a circuit for restricting a malfunction of a circuit according to a related art.

### DETAILED DESCRIPTION

Before describing embodiments of the present disclosure, difficulties which the inventors of the present disclosure found will be described below.

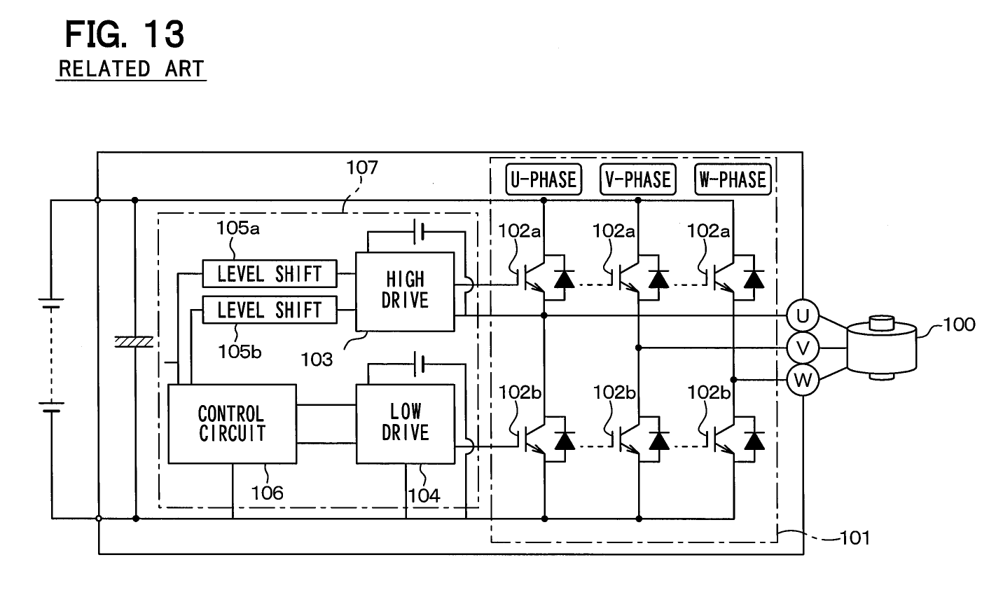

As shown in FIG. 13, a high voltage integrate circuit (HVIC) 107 used for driving an inverter circuit 101 includes a high-potential reference gate driving circuit 103, a low-potential reference gate driving circuit 104, level shift elements 105a, 105b, and a control circuit 106. The inverter circuit 101 is used for driving a motor 100 and includes high-side insulated gate bipolar transistors (IGBTs) 102a and low-side IGBTs 102b. The high-potential reference gate driving circuit 103 corresponds to a high-potential reference circuit that drives the high-side IGBTs 102a. The low-potential reference gate driving circuit 104 corresponds to a low-potential reference circuit that drives the low-side IGBTs 102b. In the HVIC 107, signals are transmitted through the level shift elements 105a, 105b so that reference voltages of the high-potential reference circuit and the low-potential reference circuit are shifted. The HVIC is formed in one chip so as to reduce a dimension of an inverter. Furthermore, a one-chip inverter including IGBTs and free wheel diodes (FWDs) is also manufactured.

However, in the HVIC formed in one chip, a potential interference may be caused between the high-potential reference circuit and the low-potential reference circuit, and the circuits may malfunction. Thus, conventionally, elements are isolated, for example, by a JI isolation structure, a dielectric isolation structure, or a trench isolation structure using a SOI substrate, for example, as disclosed in JP-A-2006-093229. However, because a potential of an output portion for driving an IGBT of the high-potential reference circuit has to be a virtual ground potential used as a reference of a high-potential side, in any of the above-described element isolation structures, when a low potential (e.g., 0 V) is changed to a high potential (e.g., 750 V) in a level shift, a high voltage (e.g., greater than 1200 V) is generated at a high rising rate of a few tens of kV/μsec, and a large high potential amplitude is generated. It is difficult to deal with the high voltage surge with a high rising rate (hereafter, referred to as dv/dt surge because a voltage rise with respect to a rise time is high) without causing a malfunction of a circuit.

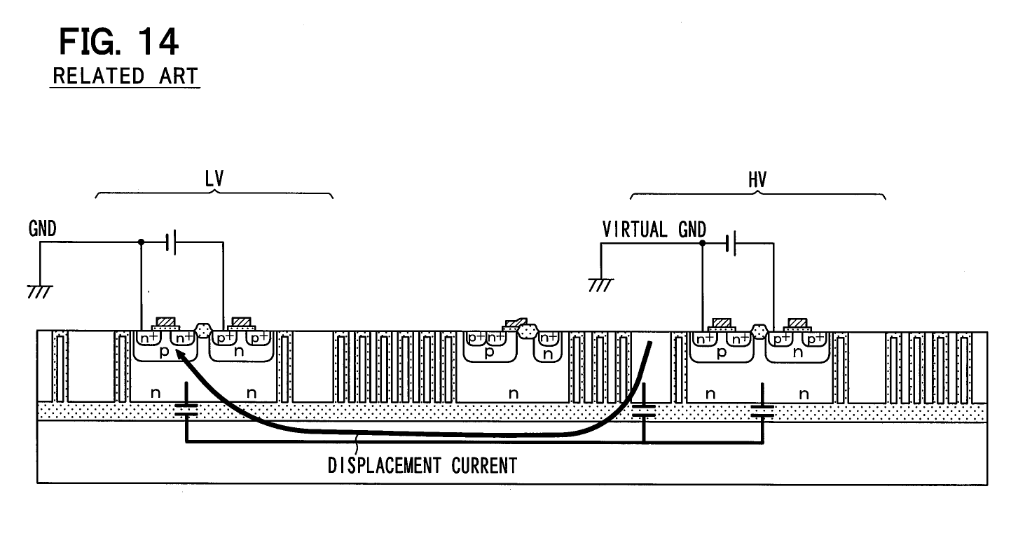

In the above-described element isolation methods, the trench isolation structure using the SOI substrate has a highest resistance with respect to noises. However, also in a HVIC having the trench isolation structure using the SOI substrate, a potential may interfere through a support substrate when dv/dt surge is applied, and a displacement current, which changes and discharges a parasitic capacitance formed in a buried oxide layer (BOX) disposed between the support substrate and the active layer, is generated, and therefore a circuit may malfunction. For example, as shown in FIG. 14, a displacement current flows from a portion at a virtual ground potential (virtual GND) in a high-potential reference circuit section HV to a support substrate through a buried oxide layer, and then the displacement current flows to a portion at a ground potential (GND) in a low-potential reference circuit section LV through the buried oxide layer.

The above-described issue of a malfunction of a circuit can be restricted by increasing a thickness of the buried oxide layer to reduce a parasitic capacitance or decreasing an impurity concentration of the support substrate to have a high resistance and to reduce a transmission of the displacement current. However, in cases where amplifier circuit having a high gain and the like are integrated, even a small displacement current may cause a malfunction, and it is difficult to restrict a malfunction completely.

One of the inventors of the present application and his colleagues filed a patent application about a semiconductor device that can restrict an inflow of a displacement current, which charges and discharges a parasitic capacitance or a junction capacitance, to an element region, and thereby restricting a malfunction of a circuit (see JP-A-2011-238760). In the semiconductor device, an n-type guard ring is disposed between a semiconductor element and a trench isolation structure surrounding the semiconductor element, and the semiconductor element is disposed in a p-type well that has a different conductivity type from the n-type guard ring.

A current pathway of low impedance is provided by disposing the n-type guard ring. Thus, the displacement current due to the parasitic capacitance by the buried oxide layer can be easily extracted from a terminal coupled with the n-type guard ring (hereafter, referred to as a guard ring terminal). Furthermore, because the semiconductor element is disposed in the p-type well, the displacement current due to the parasitic capacitance by the buried oxide layer can be effectively extracted, and an inflow of the displacement current to the element region can be restricted. Therefore, a malfunction of the circuit due to an inflow of the displacement current to the element region can be restricted.

When the above-described configuration is employed, the guard ring terminal is coupled to the highest potential in the circuit, such as an external power source. Thus, although a malfunction of the circuit due to the displacement current can be restricted by the above-described configuration, when noises enters the external power source to which the guard ring terminal is coupled, electric current may flow into the semiconductor element, and an analog circuit may malfunction.

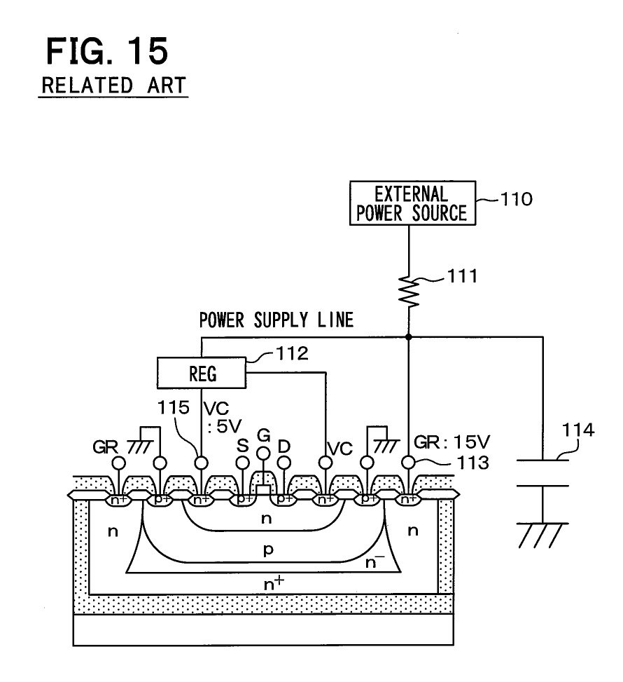

In order to solve the above-described disadvantage, it can be considered that the following circuit configuration is employed. FIG. 15 is a diagram of a p-channel type MOSFET having a configuration for restricting a malfunction of a circuit. As shown in FIG. 15, a power supply voltage is applied from an external power source 110 such as a DC-DC power source to a regulator (REG) 112 for generating a constant voltage and a guard ring terminal 113 through a resistor 111, and a bypass capacitor 114 is coupled in parallel with the regulator 112 and the guard ring terminal 113. A voltage (e.g., 5 V) generated by the regulator 112 is applied to a collector terminal 115, and the voltage (e.g., 15 V) of the external power source 110 is applied to the guard ring terminal 113. A resistor-capacitor circuit (RC circuit) including the resistor 111 and the bypass capacitor 114 can restrict noises in accordance with a time constant even when noises enter the external power source 110, and thereby restricting a malfunction of a circuit.

However, because a large current flows to a power supply line and a voltage drop is caused, the resistor 111 cannot have a high resistance value. Thus, the bypass capacitor 114 needs to have a large capacitance and the bypass capacitor 114 have to be made of an external discrete component. Accordingly, the number of components and a cost increase.

In the above-described example, the displacement current due to the parasitic capacitance by the buried oxide layer in the SOI substrate is described. However, also in an epitaxial substrate in which a semiconductor layer of a second conductivity type is epitaxially formed on a substrate of a first conductivity type, a displacement current is generated due to a junction capacitance by a PN junction of the substrate and the semiconductor layer.

The following embodiments are made in view of the above-described difficulties.

### First Embodiment

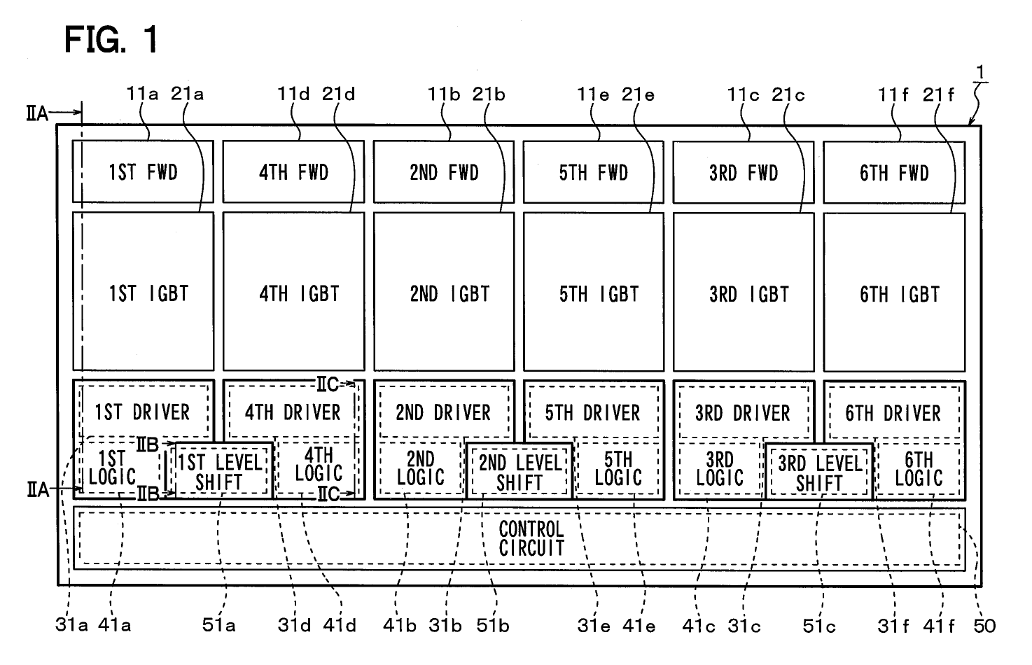

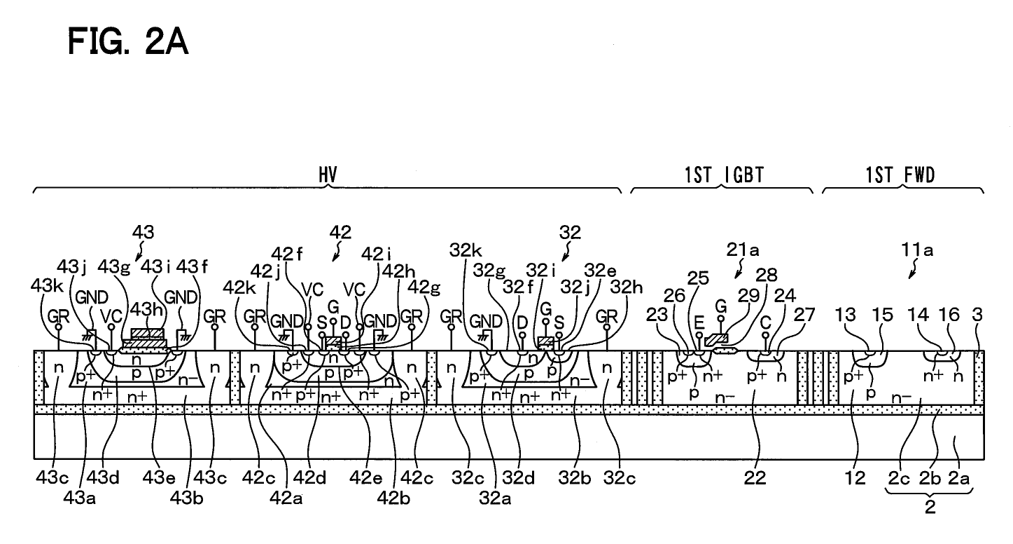

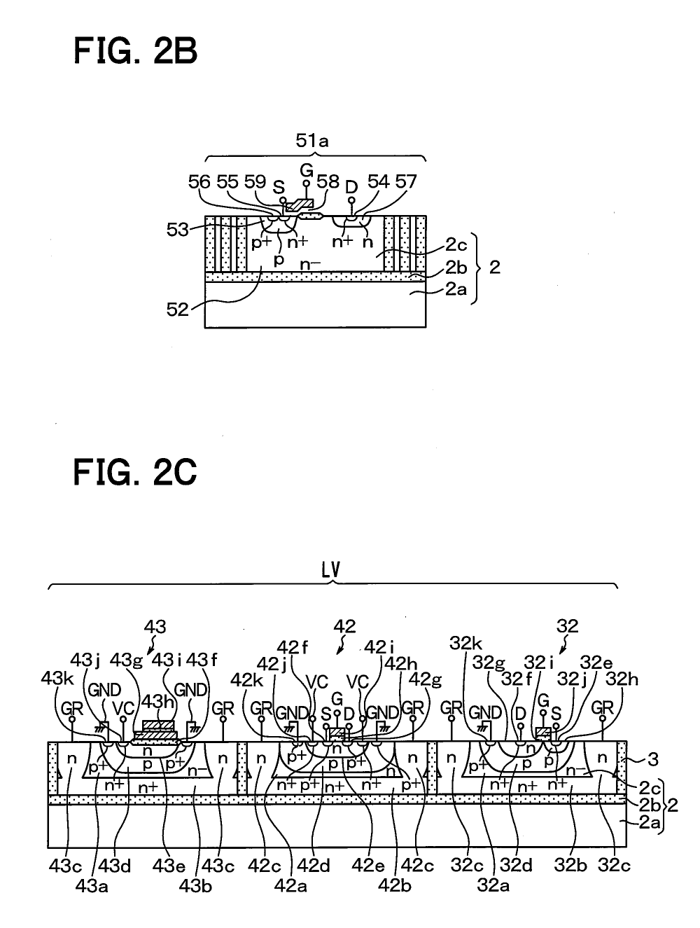

A semiconductor device 1 according to a first embodiment of the present disclosure will be described with reference to, for example, FIG. 1, FIG. 2A, FIG. 2B, and FIG. 2C. In the present embodiment, a case in which an inverter diver IC for driving a motor and the like is formed on one chip as a semiconductor device will be described as an example. In the following description, an upper side in FIG. 2 is referred to as a front surface side of the semiconductor device and a lower side in FIG. 2 is referred to as a rear surface side of the semiconductor device.

The semiconductor device shown in FIG. 1 forms an inverter circuit for driving a three-phase motor, which is not shown. In the semiconductor device, three pairs of upper arm and lower arm coupled in series are coupled in parallel with each other for three phases, and a circuit for controlling the six arms is provided. The three upper arms and the three lower arms are alternately arranged. In the example shown in FIG. 1, the upper arm and the lower arm are alternately arranged from a left side to a right side.

The semiconductor device 1 includes first to sixth free wheel diodes (FWDs) 11a-11f, first to sixth IGBTs 21a-21f, first to sixth drivers 31a-31f, first to sixth logic circuits 41a-41f, and a control circuit 50. The control circuit 50 controls semiconductor elements in each component so that a middle potential between the upper arm and the lower arm is applied to a U-phase, a V-phase, and W-phase in turn to drive the three phase motor.

Components included in the upper arm and components included in the lower arm are basically similar to each other. The first to third drivers 31a-31c and the first to third logic circuits 41a-41c included in the upper arms form a high-potential reference circuit section HV that operates using a high potential as a reference. The fourth to sixth drivers 31d-31f and the fourth to sixth logic circuits 41d-41f included in the lower arms form a low-potential reference circuit section LV that operates using a low potential as a reference. Because the potentials used as the reference differ greatly from each other, the potentials used as the reference have to be shifted. Thus, between the upper arms and the lower arms, first to third level shift elements 51a-51c are disposed.

As shown in FIG. 2A to FIG. 2C, the semiconductor device 1 includes a SOI substrate 2. The SOI substrate 2 includes a support substrate 2a made of a silicon substrate, a buried oxide layer 2b disposed on the support substrate 2a, and an active layer 2c made of a silicon layer and disposed on the buried oxide layer 2b. The active layer 2c operates as a semiconductor layer. In the active layer 2c, a trench isolation structure 3 that reaches to the buried oxide layer 2b is formed. The trench isolation structure 3 electrically isolates the semiconductor elements in the semiconductor device 1 from one another. The trench isolation structure 3 includes, for example, a trench filled with an oxide layer and polysilicon. Although the trench isolation structure 3 forms a dielectric isolation region in the present embodiment, other element isolation structure may also be employed.

As shown in FIG. 2A, the first FWD 11a is disposed in an n⁻-type drift layer 12 included in the active layer 2c. At a front surface portion of the n⁻-type drift layer 12, a p⁺-type anode layer 13 and an n⁺-type cathode layer 14 are disposed apart from one another. The p⁺-type anode layer 13 is surrounded by a p-type layer 15 that has a lower impurity concentration than the p⁺-type anode layer 13. The n⁺-type cathode layer 14 is surrounded by an n-type layer 16 that has a lower impurity concentration than the n⁺-type cathode layer 14. The first FWD 11a has the above-described structure. The second to sixth FWDs 11b-11f have the same cross-sectional structure as the cross-sectional structure of the first FWD 11a shown in FIG. 2A.

The first IGBT 21a is disposed in the n⁻-type drift layer 22 included in the active layer 2c. At a front surface portion of the n⁻-type drift layer 22, a p-type base region 23 and a p⁺-type collector region 24 are disposed apart from one another. In addition, an n⁺-type emitter region 25 is disposed so as to be surrounded by the p-type base region 23. On a front surface of the p-type base region 23, a p⁺-type contact region 26 is disposed. The p⁺-type collector region 24 is surrounded by an n-type buffer layer 27. A region of the p-type base region 23 located between the n⁺-type emitter region 25 and the p⁺-type collector region 24 operates as a channel region. On a front surface of the channel region, a gate electrode 29 is disposed through a gate insulating layer 28. Although it is not shown in the drawings, an emitter electrode, which is electrically coupled with the n⁺-type emitter region 25 and the p⁺-type contact region 26, and a collector electrode, which is electrically coupled with the p⁺-type collector region 24, are formed. The emitter electrode and the collector electrode are electrically isolated from the gate electrode 29 by an interlayer insulating layer. The emitter electrode and the collector electrode are electrically coupled with the above-described components through contact holes defined by the interlayer insulating layer. The first IGBT 21a has the above-described configuration. The second to sixth IGBTs 21b-21f have the same cross-sectional structure as the cross-sectional structure of the first IGBT 21a shown in FIG. 2A.

The first driver 31a and the first logic circuit 41a form the high potential reference circuit section HV. The first driver 31a operates as a high-side driver. The first driver 31 includes a high voltage MOSFET 32. The first logic circuit 41a includes a p-channel type MOSFET 42 and a capacitor 43.

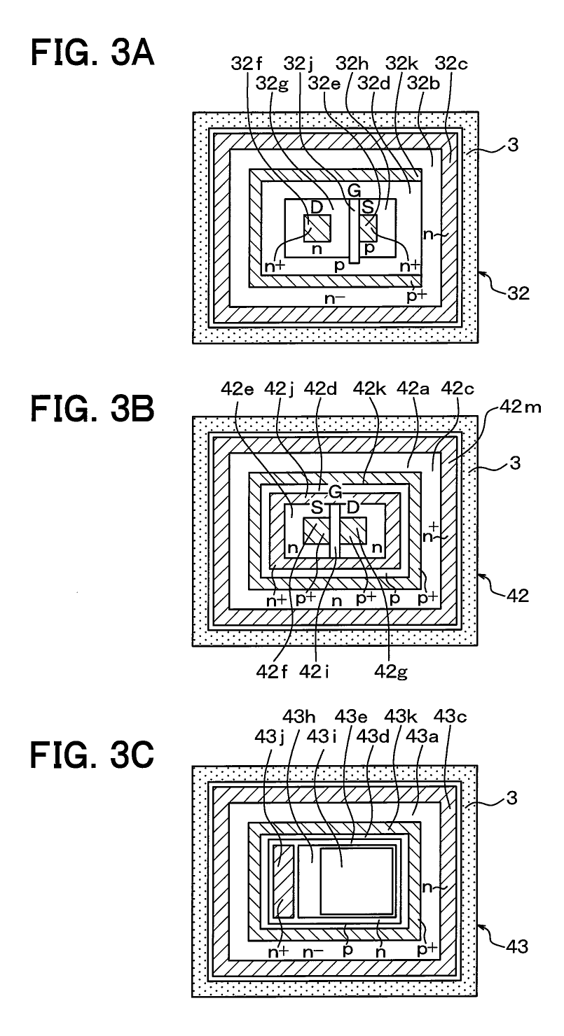

The high voltage MOSFET 32 is disposed in an n⁻-type drift layer 32a included in the active layer 2c. At a rear surface portion of the n⁻-type drift layer 32a adjacent to the buried oxide layer 2b, an n⁺-type buried region 32b having a higher impurity concentration than the active layer 2c is disposed. Furthermore, as shown in FIG. 2A, an n-type guard ring 32c extends from a front surface of the n⁻-type drift layer 32a to the n⁺-type buried region 32b. The n-type guard ring 32c has a higher conductivity than the active layer 2c. As shown in FIG. 3A, the n-type guard ring 32c surrounds a portion of the n⁻-type drift layer 32a forming the high voltage MOSFET 32. For example, the n-type guard ring 32c has a peak concentration of 8×10¹⁹ cm⁻³, a width of 7.4 μm, and a junction depth of 8.0 μm.

The n⁺-type buried region 32b and the n-type guard ring 32c are applied with a voltage GR. In the n⁻-type drift layer 32a surrounded by the n⁺-type buried region 32b and the n-type guard ring 32c, a p-type well 32d is disposed. In the p-type well 32d, components forming the high voltage MOSFET 32 are disposed.

At a front surface portion of the p-type well 32d, an n⁺-type source region 32e and an n⁺-type drain region 32f are disposed apart from one another. The n⁺-type drain region 32f is surrounded by an n-type well 32g that has a lower impurity concentration than the n⁺-type drain region 32f and that operates as a buffer layer. The n⁺-type source region 32e is surrounded by a p-type region 32h having a higher impurity concentration than the p-type well 32d. In the p-type well 32d, a front surface portion of a region located between the n⁺-type source region 32e and the n-type well 32g operates as a channel region. In the channel region, a gate electrode 32j is disposed through a gate insulating layer 32i.

Although it is not shown in the drawings, a source electrode is electrically coupled with the n⁺-type source region 32e and the p-type region 32h, and a drain electrode is electrically coupled with the n⁺-type drain region 32f. The emitter electrode and the collector electrode are electrically isolated from the gate electrode 32j by an interlayer insulating layer. The emitter electrode and the collector electrode are electrically coupled with the above-described components through contact holes defined by the interlayer insulating layer. Furthermore, a p⁺-type well contact region 32k is disposed at a part of a peripheral portion of the p-type well 32d. The p-type well 32d is fixed to a ground potential (GND) through the p⁺-type well contact region 32k. The high voltage MOSFET 32 has the above-described configuration.

The p-channel type MOSFET 42 is disposed in an n⁻-type layer 42a included in the active layer 2c. At a rear surface portion of the n⁻-type layer 42a adjacent to the buried oxide layer 2b, an n⁺-type buried region 42b having a higher impurity concentration than the active layer 2c is disposed. Furthermore, as shown in FIG. 2A, an n-type guard ring 42c extends from a front surface of the n⁻-type layer 42a to the n⁺-type buried region 42b. The n-type guard ring 42c has a higher conductivity than the active layer 2c. As shown in FIG. 3B, the n-type guard ring 42c surrounds a portion of the n⁻-type layer 42a forming the p-channel type MOSFET 42. The n⁺-type buried region 42b and the n-type guard ring 42c are applied with the voltage GR. In the n⁻-type layer 42a surrounded by the n⁺-type buried region 42b and the n-type guard ring 42c, a p-type well 42d is disposed. In the p-type well 42d, components forming the p-channel type MOSFET 42 are disposed.

At a front surface portion of the p-type well 42d, an n-type well 42e is disposed. In the n-type well 42e, a p⁺-type source region 42f and a p⁺-type drain region 42g are disposed apart from one another. In the n-type well 42e, a region located between the p⁺-type source region 42f and the p⁺-type drain region 42g operates as a channel region. On a front surface of the channel region, a gate electrode 42i is disposed through a gate insulating layer 42h. At a peripheral portion of the n-type well 42e, an n⁺-type well contact region 42j having a higher impurity concentration than the n-type well 42e is disposed. The n-type well 42e is applied with the power supply voltage VC through the n⁺-type well contact region 42j. At a peripheral portion of the p-type well 42d, a p⁺-type well contact region 42k is disposed. The p-type well 42d is fixed to the ground potential (GND) through the p⁺-type well contact region 42k. The p-channel type MOSFET 42 has the above-described configuration.

The capacitor 43 is a two-layer poly type capacitor made of doped polysilicon. The capacitor 43 is disposed in the n⁻-type layer 43a included in the active layer 2c. At a rear surface portion of the n⁻-type layer 43a adjacent to the buried oxide layer 2b, an n⁺-type buried region 43b having a higher impurity concentration than the active layer 2c is disposed. Furthermore, as shown in FIG. 2A, an n-type guard ring 43c extends from a front surface of the n⁻-type layer 43a to the n⁺-type buried region 43b. The n-type guard ring 43c has a higher conductivity than the active layer 2c. As shown in FIG. 3C, the n-type guard ring 43c surrounds a portion of the n⁻-type layer 43a forming the capacitor 43. The n⁺-type buried region 43b and the n-type guard ring 43c are applied with the voltage GR. In the n⁻-type layer 43a surrounded by the n⁺-type buried region 43b and the n-type guard ring 43c, a p-type well 43d is disposed. In the p-type well 43d, components forming the capacitor 43 are disposed.

At a surface portion of the p-type well 43d, an n-type well 43e is disposed. In the n-type well 43e, a local oxidation of silicon (LOCOS) oxide layer 43f is disposed. On the LOCOS oxide layer 43f, a first electrode 43g, an insulating layer 43h, and a second electrode 43i are stacked. The first electrode 43g and the second electrode 43i are made of doped polysilicon. At a peripheral portion of the n-type well 43e, an n⁺-type well contact region 43j having a high impurity concentration than the n-type well 43e is disposed. The n-type well 43e is applied with the power supply voltage VC through the n⁺-type well contact region 43j. At a peripheral portion of the p-type well 43d, a p⁺-type well contact region 43k is disposed. The p-type well 43d is fixed to the ground potential (GND) through the p⁺-type well contact region 43k. In the capacitor 43 having the above-described configuration, the insulating layer 43h operates as a capacitance layer, and the first electrode 43g and the second electrode 43i operates as two electrodes of the capacitor 43.

The second driver 31b and the third driver 31c have the same cross-sectional structure as the first driver 31a. The second logic circuit 41b and the third logic circuit 41c have the same cross-sectional structure as the first logic circuit 41a.

As shown in FIG. 2B, the first level shift element 51a includes a high voltage laterally defused metal-oxide semiconductor (high voltage LDMOS). The first level shift element 51a is formed in an n⁻-type drift layer 52 included in the active layer 2c. At a front surface portion of the n⁻-type layer, a p-type base region 53 and an n⁺-type drain region 54 are disposed apart from one another. The p-type base region 53 surrounds an n⁺-type source region 55. At a front surface portion of the p-type base region 53, a p⁺-type contact region 56 is formed. The n⁺-type drain region 54 is surrounded by an n-type buffer layer 57. In the p-type base region 53, a region located between the n⁺-type source region 55 and the n⁺-type drain region 54 operates as a channel region. On a front surface of the channel region, a gate electrode 59 is disposed through a gate insulating layer 58. Although it is not shown in the drawings, a source electrode is electrically coupled with the n⁺-type source region 55 and the p⁺-type contact region 56, and a drain electrode is electrically coupled with the n⁺-type drain region 54. The source electrode and the drain electrode are electrically isolated from the gate electrode 59 by an interlayer insulating layer. The source electrode and the drain electrode are electrically coupled with the above-described components through contact holes defined by the interlayer insulating layer. The first level shift element 51a have the above-described configuration. The second level shift element 51b and the third level shift element 51c have the same cross-sectional structure as the first level shift element 51a.

The fourth driver 31d and the fourth logic circuit 41d form the low potential reference circuit section LV shown in FIG. 2C. The fourth driver 31d operates as a low-side driver. Components included in the fourth driver 31d and the fourth logic circuit 41 are similar to the above-described components included in the first driver 31a and the first logic circuit 41a, respectively. The fifth driver 31e and the sixth driver 31f have the same cross-sectional structure as the first driver 31a, and the fifth logic circuit 41e and the sixth logic circuit 41f have the same cross-sectional structure as the first logic circuit 41a.

The semiconductor device 1 according to the present embodiment has the above-described configuration. The semiconductor device 1 can have a current pathway of low impedance due to the n⁺-type buried regions 32b, 42b, 43b and the n-type guard rings 32c, 42c, 43c included in the components of the high potential reference circuit section HV and the low potential reference circuit section LV. Thus, the displacement current due to the parasitic capacitance by the buried oxide layer 2b can be easily extracted from terminals coupled with the n-type guard sings 32c, 42c, 43c (hereafter, referred to as guard ring terminals).

The high voltage MOSFET 32, the p-channel type MOSFET 42 and the capacitor 43 are respectively disposed in the p-type wells 32d, 42d, 43d having the different conductivity type from the n⁺-type buried regions 32b, 42b, 43b and the n-type guard rings 32c, 42c, 43c. Thus, the junction capacitances are provided between the active layer 2c and the p-type wells 32d, 42d, 43d. Due to the junction capacitances, impedances of pathways through which the displacement current flows to the high voltage MOSFET 32, the p-channel type MOSFET 42, and the capacitor 43 increase. Thus, an inflow of the displacement current to the high voltage MOSFET 32, the p-channel type MOSFET 42 and the capacitor 43 can be restricted.

Furthermore, because other junction capacitances are provided between the p-type wells 42d, 43d and the n-type wells 42e, 43e disposed in the p-type wells 42d, 43d, an inflow of the displacement current can be further restricted.

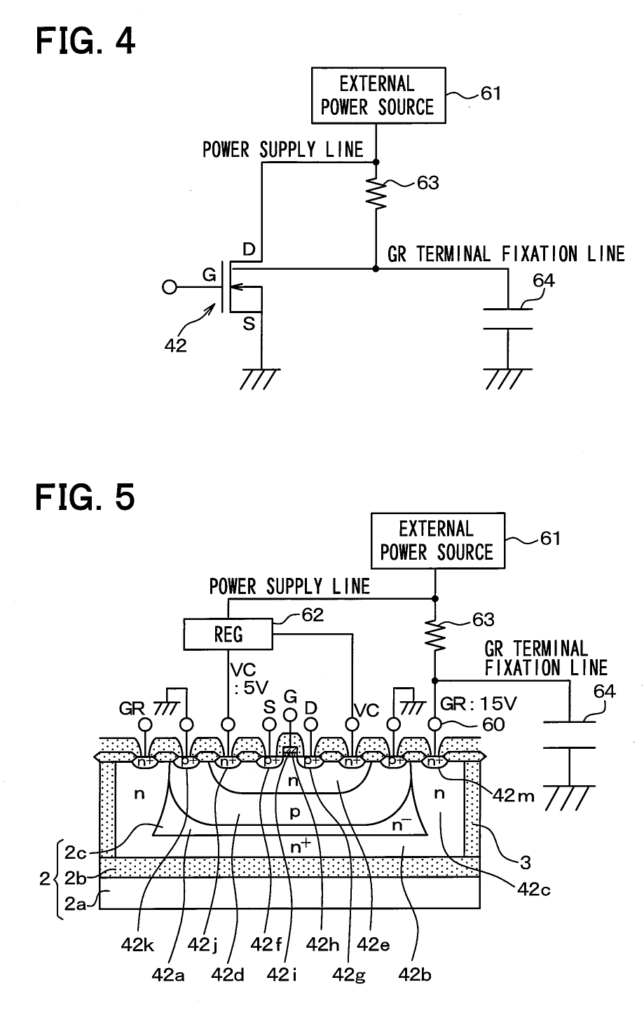

The semiconductor device 1 may have the following circuit configuration. A circuit configuration and a coupling configuration of the p-channel type MOSFET 42 will be described with reference to FIG. 4 and FIG. 5. Circuit configurations and coupling configurations of other semiconductor elements having the guard ring structure are similar to the circuit configuration and the coupling configuration of the p-channel type MOSFET 42.

The p-channel type MOSFET 42 includes a source terminal, a drain terminal, and a gate terminal. As shown in FIG. 4, the source terminal is coupled to the ground, the drain terminal is coupled to the power supply line though which power is supplied from the external power source 61 such as the DC-DC power source, and the gate terminal is applied to a gate voltage from the control circuit 50. In the p-channel type MOSFET 42, the n-type guard ring 42c is coupled to the external power source 61 through a guard ring (GR) terminal fixation line which is different from the power supply line. Thus, a line coupled with the external power source 61 is divided into the power supply line and the guard ring terminal fixation line. On the guard ring terminal fixation line, a resistor 63 and a bypass capacitor 64 are disposed. The guard ring terminal is coupled with a point between the resistor 63 and the bypass capacitor 64 so that the bypass capacitor 64 is coupled in parallel with the guard ring structure. Because of the resistor 63, a resistance value of the guard ring terminal fixation line between external power source 61 and the bypass capacitor 64 is higher than a resistance value of the power supply line between the external power source 61 and the p-channel type MOSFET 42. Accordingly, a capacitance of the bypass capacitor 64 can be reduced. By the above-described configuration, a potential of the guard ring terminal is fixed to a potential between the resistor 63 and the bypass capacitor 64.

As shown in FIG. 3B and FIG. 5, an n⁺-type contact region 42m is disposed on a front surface of the n-type guard ring 42c in the p-channel type MOSFET 42. Electrode material and the like is brought into contact with the n⁺-type contact region 42m so as to form a guard ring terminal 60. The guard ring terminal 60 is electrically coupled with the n-type guard ring 42c through the n⁺-type contact region 42m.

The line coupled with the external power source 61 is divided into the power supply line and the guard ring terminal fixation line. The regulator 62 is coupled to the power supply line. The guard ring terminal 60 is coupled to the guard ring terminal fixation line. The regulator 62 is coupled with the external power source 61 through the power supply line. The regulator 62 generates the power supply voltage (e.g., 5 V) corresponding to a first constant voltage, and the power supply voltage VC is applied to the n⁺-type well contact region 42j. On the guard ring terminal fixation line, the resistor 63 and the bypass capacitor 64 are disposed. The resistor 63 and the bypass capacitor 64 are coupled through the guard ring terminal fixation line, and the guard ring terminal 60 is coupled to a coupling point of the resistor 63 and the bypass capacitor 64 so that the guard ring terminal 60 is applied with the voltage GR (e.g., 15 V) generated by the external power source 61 and corresponding to a second constant voltage. In other words, the bypass capacitor 64 is coupled in parallel with the guard ring terminal 60 and the guard ring terminal 60 is fixed to the voltage GR by the bypass capacitor 64. Although the example shown in FIG. 5 includes the regulator 62, the regulator 62 is not always necessary.

Even when noises enter the external power source 61, an RC circuit including the resistor 63 and the bypass capacitor 64 can restrict the noises in accordance with a time constant of the RC circuit, and thereby restricting a malfunction of the circuit.

In the above-described configuration, the power supply line and the guard ring terminal fixation line can be divided. Therefore, a large current that flows in the power supply line does not flow to the resistor 63 disposed on the guard ring terminal fixation line. In other words, because the power supply line and the guard ring terminal fixation line are divided at a position between the external power source 61 and the resistor 63, the large current that flows in the power supply line does not flow to the resistor 63, and only a small current that flows in the guard ring terminal fixation line flows to the resistor 63. Thus, the resistance value of the resistor 63 disposed on the line for fixing the potential of the guard ring terminal 60 can be increased. Accordingly, compared with cases where the resistor 63 is disposed on the power supply line, a time constant of the RC circuit for restricting noises can be obtained even when the capacitance of the bypass capacitor 64 is reduced. Therefore, the bypass capacitor 64 does not have to be a discrete component.

As described above, in the present embodiment, the line coupled with the external power source 61 is divided into the power supply line and the guard ring terminal fixation line, and the resistor 63 is disposed on the guard ring terminal fixation line in which the electric current that flows in the power supply line does not flow. Accordingly, the bypass capacitor 64 does not have to be a discrete component. Therefore, the semiconductor device 1 can restrict a malfunction of the circuit by restricting an inflow of the displacement current, which charges and discharges the parasitic capacitance or the junction capacitance, to the element region. The semiconductor device 1 further restricts a malfunction of the circuit by the RC circuit when noises enter the external power source.

In cases where a protective diode for surge protection is coupled to a gate of each MOSFET, a capacitance of the protective diode is not sufficient to operate as a bypass capacitor. By disposing the bypass capacitor 64 as described in the present embodiment, a sufficient capacitance, which is not obtained by the capacitance component of the protective diode, can be obtained.

### Second Embodiment

A semiconductor device according to a second embodiment of the present disclosure will be described. In the present embodiment, a configuration of a bypass capacitor 64 is changed from the configuration of the bypass capacitor 64 described in the first embodiment, and the other parts are similar to the first embodiment. Thus, a part different from the first embodiment will be mainly described.

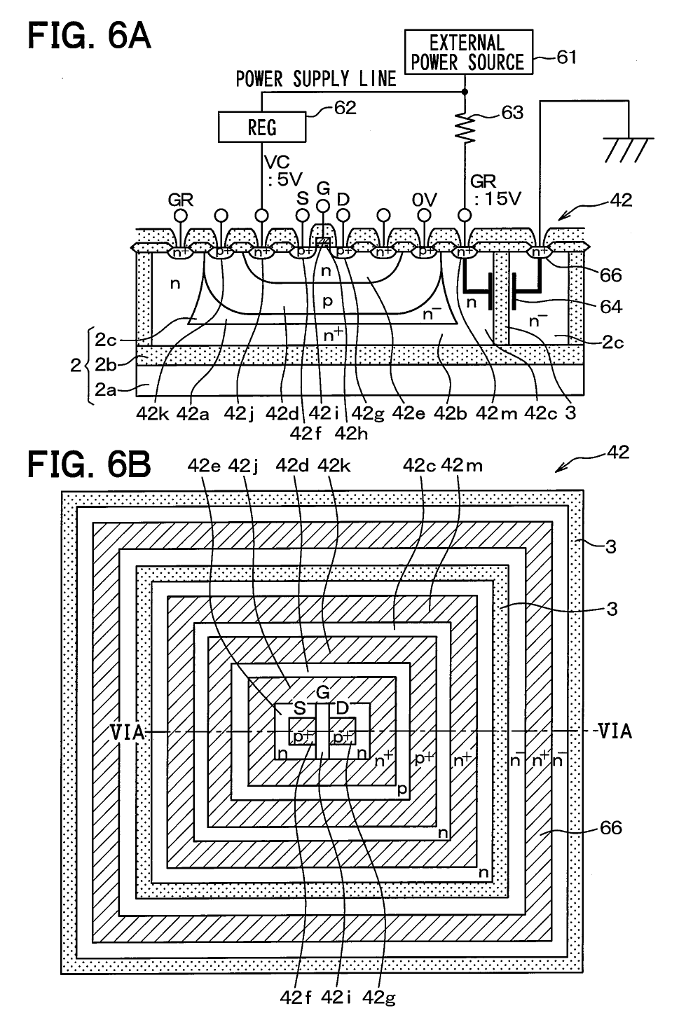

In FIG. 6A and FIG. 6B, a circuit configuration of the p-channel type MOSFET 42 is shown as an example of a circuit configurations of semiconductor elements. FIG. 6A corresponds to a cross section taken along line VIA-VIA in FIG. 6B. The similar configuration can be applied to circuit configurations of other semiconductor elements.

As shown in FIG. 6A and FIG. 6B, in the present embodiment, the trench isolation structure 3 operates as a bypass capacitor 64. The trench isolation structure 3 is doubly-arranged to surround the semiconductor element. In other words, the trench isolation structure 3 includes a first trench isolation ring and a second trench isolation ring surrounding the first trench isolation ring. At a region adjacent to the semiconductor element through the trench isolation structure 3, that is, at the region sandwiched by the first trench isolation ring and the second trench isolation ring, an n⁺-type contact region 66 is disposed at a front surface portion of the active layer 2c. The n⁺-type contact region 66 is coupled to the ground through the guard ring terminal fixation line. The guard ring fixation line includes a pathway that passes through the resistor 63, the guard ring terminal 60, the n⁺-type contact region 42m, the n-type guard ring 42c, the bypass capacitor 64 formed of the trench isolation structure 3, the active layer 2c, and the n⁺-type contact region 66 in this order.

In this way, the bypass capacitor 64 may by formed of the trench isolation structure 3. In cases where the semiconductor device 1 has the above-described configuration, the bypass capacitor 64 may be disposed in an IC chip forming the semiconductor device 1. The trench isolation structure 3 is generally formed by filling a trench with an oxide layer and polysilicon. For example, the bypass capacitor 64 may have the following configuration.

### Modification of Second Embodiment

In the second embodiment, the trench isolation structure 3 is formed by filling a trench with an oxide layer and polysilicon. In order to obtain a larger capacitance, a material used in the trench isolation structure 3 may be changed.

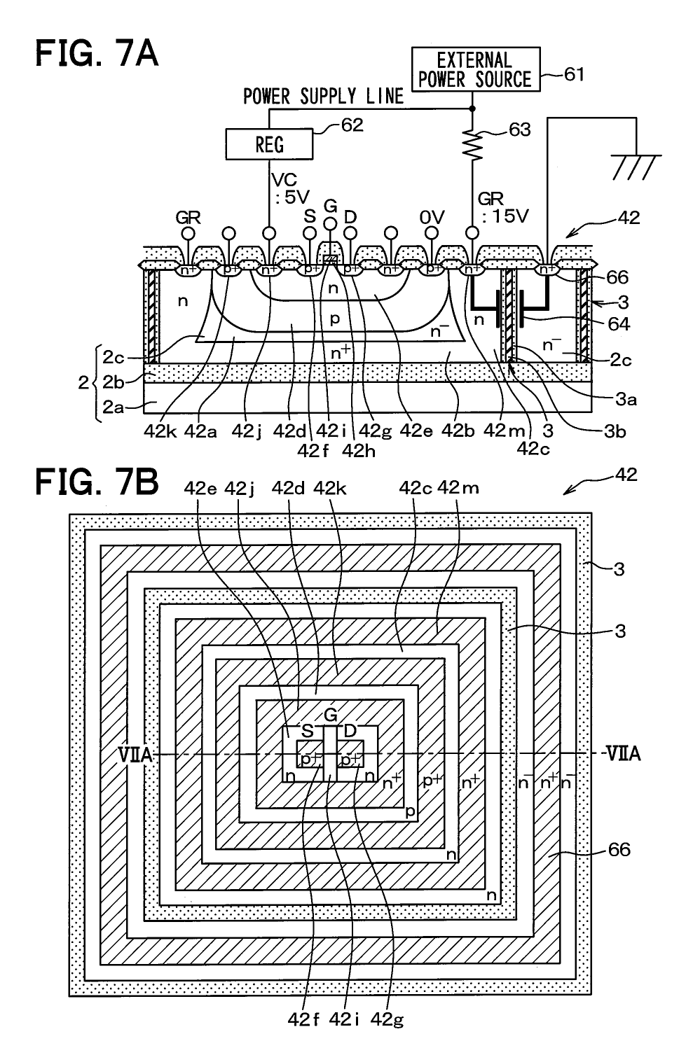

In FIG. 7A and FIG. 7B, a circuit configuration of a p-channel type MOSFET 42 in which a material used in the trench isolation structure 3 is changed is shown. FIG. 7A corresponds to a cross section taken along line VIIA-VIIA in FIG. 7B.

As shown in FIG. 7A and FIG. 7B, a surface of a trench is covered with an oxide layer 3a, and a high dielectric constant layer 3b is disposed on the oxide layer 3a to form the trench isolation structure 3. When the bypass capacitor 64 is formed of the above-described trench isolation structure 3, the capacitance of the bypass capacitor 64 can be increased.

### Third Embodiment

A semiconductor device 1 according to a third embodiment of the present disclosure will be described. In the present embodiment, a configuration of a bypass capacitor 64 is changed from the configuration of the bypass capacitor 64 described in the second embodiment, and the other parts are similar to the second embodiment. Thus, a part different from the first embodiment will be mainly described.

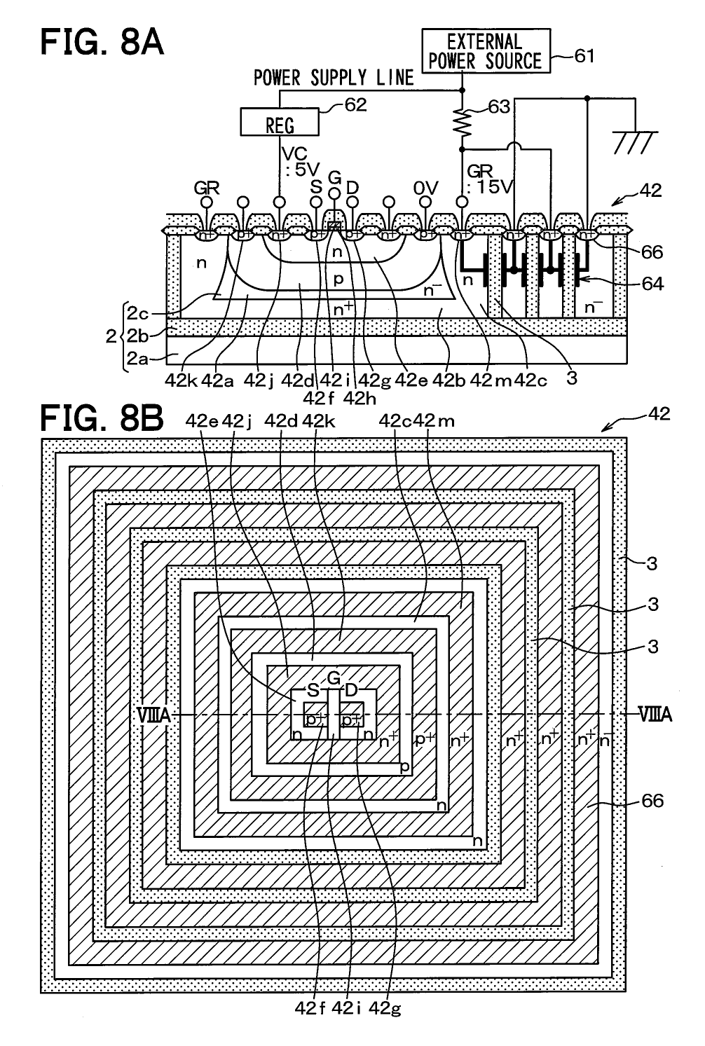

In FIG. 8A and FIG. 8B, a circuit configuration of a p-channel type MOSFET 42 according to the present embodiment is shown. FIG. 8A corresponds to a cross section taken along line VIIIA-VIIIA in FIG. 8B. The similar configuration can be applied to circuit configurations of other semiconductor elements.

As shown in FIG. 8A and FIG. 8B, in the present embodiment, a bypass capacitor 64 includes a multiply-arranged trench isolation structure 3 so that the bypass capacitor 64 can have a large capacitance. For example, the trench isolation structure 3 is triply-arranged to surround the semiconductor element. In other words, the trench isolation structure 3 includes a first trench isolation ring, a second trench isolation ring, and a third trench isolation ring disposed concentrically and surrounding the semiconductor element. In each region divided by the first trench isolation ring, the second trench isolation ring, and the third trench isolation ring, the n⁺-type contact region 66 is disposed at a front surface portion of the active layer 2c. Capacitors provided by the triply-arranged trench isolation structure 3 are coupled in parallel with each other. In other words, the first trench isolation ring, the second trench isolation ring, and the third trench isolation ring are coupled in parallel with each other. In cases where the bypass capacitor 64 is formed of the multiply-arranged trench isolation structure 3 and each trench isolation ring of the trench isolation structure 3 are coupled in parallel with the other trench isolation rings, the capacitance of the bypass capacitor 64 can be further increased.

In the configuration of the present embodiment, the trench isolation structure 3 may by formed by filling a trench with the oxide layer 3a and the high dielectric constant layer 3b so as to further increase the capacitance of the bypass capacitor 64. Furthermore, in cases where the bypass capacitor 64 is formed by a trench isolation structure 3 including more than three trench isolation rings, the capacitance of the bypass capacitor 64 can be further increased.

### Fourth Embodiment

A semiconductor device 1 according to a fourth embodiment of the present disclosure will be described. Also in the present embodiment, a configuration of a bypass capacitor 64 is changed from the configuration of the bypass capacitor 64 described in the second embodiment, and the other parts are similar to the second embodiment. Thus, a part different from the first embodiment will be mainly described.

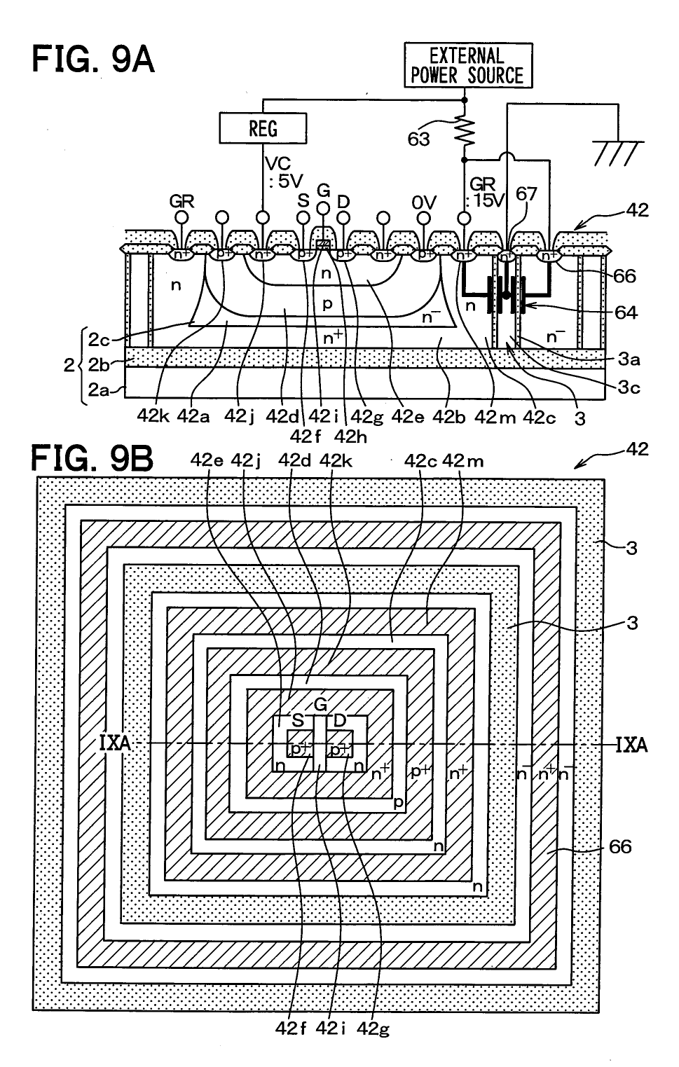

In FIG. 9A and FIG. 9B, a circuit configuration of a p-channel type MOSFET 42 is shown as an example of a circuit configurations of semiconductor elements. FIG. 9A corresponds to a cross section taken along line VIIIA-VIIIA in FIG. 9B. The similar configuration can be applied to circuit configurations of other semiconductor elements.

As shown in FIG. 9A and FIG. 9B, also in the present embodiment, the trench isolation structure 3 is used as a bypass capacitor 64. The trench isolation structure 3 includes an oxide layer 3a and a polysilicon layer 3c. The oxide layer 3a disposed on two sidewalls of a trench, that is, located on either side of the polysilicon layer 3c operates as a capacitor. Accordingly, the trench isolation structure 3 operates as the bypass capacitor 64. Specifically, an n⁺-type contact region 66 id disposed on a front surface of a region of the active layer 2c located adjacent to the semiconductor element through the trench isolation structure 3. In addition, an n⁺-type contact region 67 is disposed on a surface of the polysilicon layer 3c in the trench isolation structure 3. Each oxide layer 3a is coupled in parallel with each other to form the bypass capacitor 64.

In this way, the bypass capacitor 64 may be formed of the oxide layer 3a disposed on two sidewalls of the trench included in the trench isolation structure 3, which forms two capacitor. In the present case, a larger capacitance value can be obtained compared with a case where the trench isolation structure 3 forms one capacitor as described in the first embodiment.

### Other Embodiments

In each of the above-described embodiments, the n-type guard rings 32c, 42c, 43c surrounds the whole periphery of the semiconductor element, as examples. Even when a guard ring surrounds a part of a periphery of a semiconductor element, a displacement current can be extracted.

In each of the above-described embodiments, the p-channel type MOSFET 42 including the n⁺-type buried region 42b is described as an example.

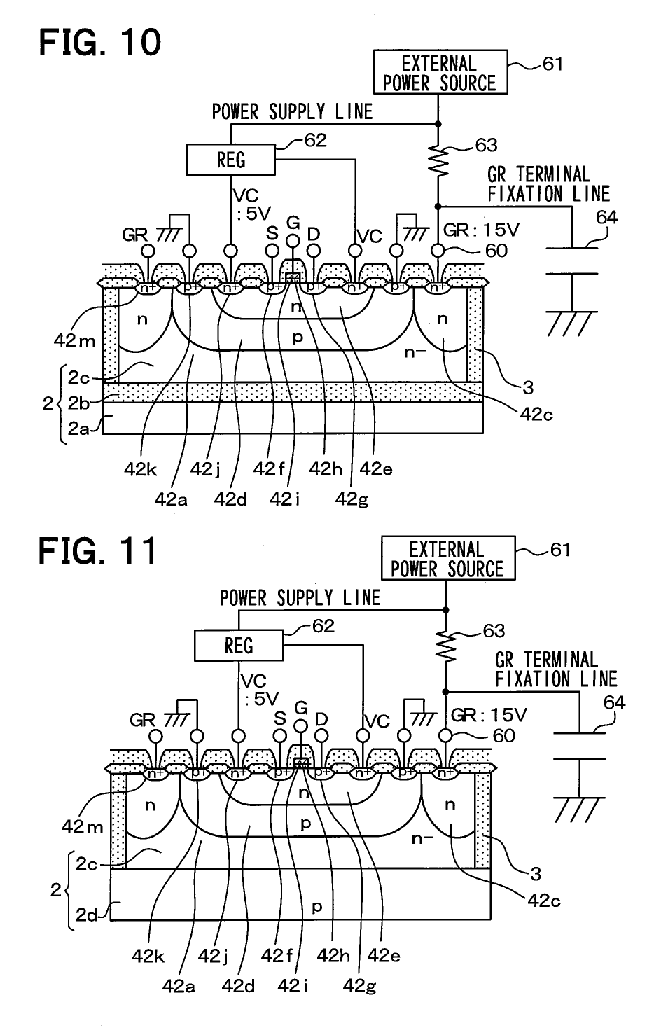

As shown in FIG. 10, the p-channel type MOSFET 42 may also have a configuration in which an n⁺-type buried region is not disposed and only the n-type guard ring 42c is disposed. In another example, a part of the semiconductor elements included in the low potential reference circuit section LV and the high potential reference circuit section HV may include an n⁺-type buried region. The above-described semiconductor elements included in the semiconductor device 1 are merely examples, and the present disclosure may also be applied to other semiconductor elements. When the first conductivity type is n-type and the second conductivity is p-type, the p-channel type MOSFET 42 is a semiconductor element that forms a p-type channel of the second conductivity type. The present disclosure may also be applied to an n-channel type MOSFET in which the conductivity types are switched so that the first conductivity type is p-type and the second conductivity type is n-type.

In each of the above-described embodiments, the semiconductor device 1 is formed using the SOI substrate 2. As shown in FIG. 11, the semiconductor device 1 may also be formed using an epitaxial substrate in which an epitaxial layer is formed on a silicon substrate. As shown in FIG. 11, the above-described configuration may be formed using a semiconductor substrate in which a semiconductor layer 2c of the second conductivity type is formed on a substrate 2d of the first conductivity type. Also in the present case, when an element region isolated by a trench isolation structure 3 is formed, a bypass capacitor 64 as described in the second to fourth embodiment may be formed of the trench isolation structure 3.

In each of the above-described embodiments, the n-type guard rings 32c, 42c, 43c extend to positions deeper than the p-type wells 32d, 42d, 43d. However, the n-type guard rings 32c, 42c, 43c do not always have to extend to the positions deeper than the p-type wells 32d, 42d, 43d.

In each of the second to fourth embodiments, the bypass capacitor 64 is formed of the trench isolation structure 3. The bypass capacitor 64 may also be formed of other capacitor. For example, the bypass capacitor 64 may be a polysilicon capacitor that is formed by forming a first polysilicon layer on a surface of a substrate through an insulation layer and further forming a second polysilicon layer on the first polysilicon layer through an insulating layer. The bypass capacitor 64 may also be a metal capacitor made of metal and having a structure similar to the polysilicon capacitor. Also in the above-described cases, by disposing a high dielectric constant layer as the insulating layer between the polysilicon layers or metal layers, the bypass capacitor 64 can have a large capacitance.

The bypass capacitor 64 may be shared by a plurality of semiconductor elements. Alternatively, the bypass capacitor 64 may be provided for each semiconductor element.

Similarly, the resistor 63 may have various configurations. For example, the resistor 63 may be one of a wiring resistor formed of a wiring pattern on a surface of a substrate, a thin film resistor stacked through an interlayer insulating layer, and a diffused resistor formed in a semiconductor substrate. The resistor 63 may also be combination of two or more of the wiring resistor, the thin-film layer, and the diffused resistor.

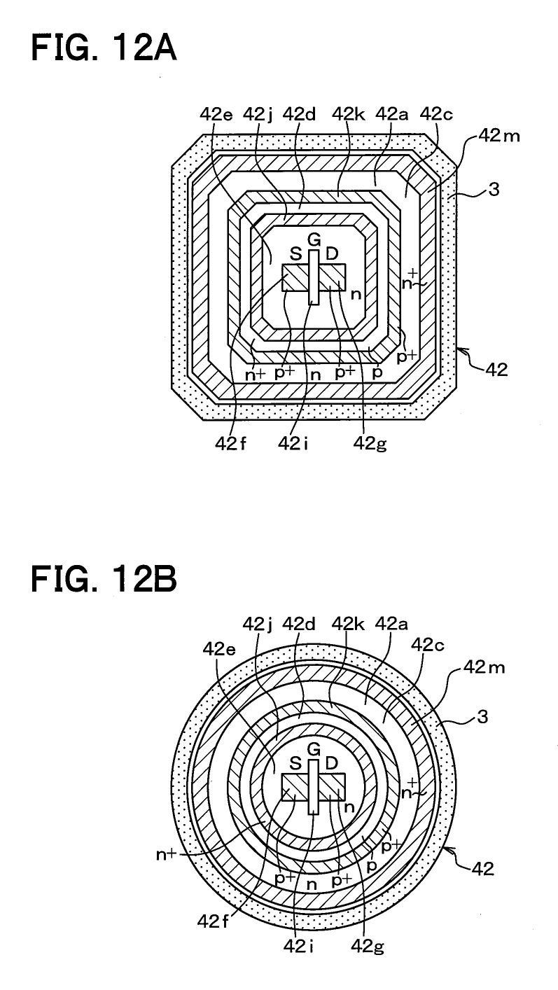

In each of the above-described embodiments, the trench isolation structure 3 has a quadrangular shape in a plane parallel to the SOI substrate 2. The trench isolation structure 3 may also have other shape. For example, the trench isolation structure 3 surrounding the p-channel type MOSFET 42 may also have an octagonal shape in a plane parallel to the SOI substrate 2 as shown in FIG. 12A, and a circular shape in a plane parallel to the SOI substrate 2 as shown in FIG. 12B. In cases where the trench isolation structure 3 have the octagonal shape or the circular shape, an angle of corners can be increased or corners can be eliminated. Thus, an electric field concentration can be relaxed and a dielectric breakdown of the trench isolation structure 3 can be restricted. Circuit configurations of other semiconductor elements may be similar to the above-described circuit configurations of the p-channel type MOSFET 42.

What is claimed is:

1. A semiconductor device comprising:
a semiconductor substrate;
a semiconductor element disposed in the semiconductor substrate;
a guard ring disposed in the semiconductor substrate and surrounding at least a part of a periphery of the semiconductor element;
a guard ring terminal coupled with the guard ring;
a power supply line divided from a line coupled with a power source and applying a first constant voltage to the semiconductor element based on a voltage generated by the power source;
a guard ring terminal fixation line divided from the line coupled with the power source and applying a second constant voltage to the guard ring terminal;
a bypass capacitor disposed on the guard ring terminal fixation line so as to be coupled in parallel with the guard ring; and
a resistor disposed on the guard ring terminal fixation line between the power source and the bypass capacitor.

2. The semiconductor device according to claim 1,
wherein the guard ring terminal fixation line between the power source and the bypass capacitor has a higher resistance value than the power supply line between the power source and the semiconductor element because of the resistor.

3. A semiconductor device comprising:
a semiconductor substrate formed of a silicon-on-insulator substrate including a support substrate, a buried oxide layer disposed on the support substrate, and a semiconductor layer of a second conductivity type disposed on the buried oxide layer;
a well of a first conductivity type disposed in an element region in the semiconductor layer;
a dielectric isolation region surrounding the element region;
a semiconductor element disposed in the well;
a guard ring having a higher conductivity than the semiconductor layer and surrounding at least a part of a periphery of the well;
a guard ring terminal coupled with the guard ring;
a power supply line divided from a line coupled with a power source and applying a first constant voltage to the semiconductor element based on a voltage generated by the power source;
a guard ring terminal fixation line divided from the line coupled with the power source and applying a second constant voltage to the guard ring terminal; and
a resistor and a bypass capacitor disposed on the guard ring terminal fixation line,
wherein a potential of the guard ring terminal is fixed to a potential between the resistor and the bypass capacitor.

4. A semiconductor device comprising:
a semiconductor substrate including a substrate of a first conductivity type and a second layer of a second conductivity type disposed on the substrate;
a well of the first conductivity type disposed in the semiconductor layer;
a semiconductor element disposed in the well;
a guard ring having a higher conductivity than the semiconductor layer and surrounding at least a part of a periphery of the well;
a guard ring terminal coupled with the guard ring;
a power supply line divided from a line coupled with a power source and applying a first constant voltage to the semiconductor element based on a voltage generated by the power source;
a guard ring terminal fixation line divided from the line coupled with the power source and applying a second constant voltage to the guard ring terminal; and
a resistor and a bypass capacitor disposed on the guard ring terminal fixation line,
wherein a potential of the guard ring terminal is fixed to a potential between the resistor and the bypass capacitor.

5. The semiconductor device according to claim 1,
wherein the bypass capacitor includes a trench isolation structure,
wherein the trench isolation structure includes a trench provided in the semiconductor substrate and surrounding the semiconductor element, and an insulating layer disposed in the trench, and
wherein the trench isolation structure defines an element region that is isolated from an outside by the trench isolation structure.

6. The semiconductor device according to claim 5, further comprising a contact region,
wherein the trench isolation structure includes a first trench isolation ring and a second trench isolation ring surrounding the first trench isolation ring,
wherein the contact region is disposed on a surface of a region of the semiconductor substrate located between the first trench isolation ring and the second trench isolation ring, and
wherein the guard ring terminal fixation line includes a pathway that passes through the bypass capacitor formed of the trench isolation structure, the region of the semiconductor substrate located between the first trench isolation ring and the second trench isolation ring, and the contact region.

7. The semiconductor device according to claim 5,
wherein the trench isolation structure includes a plurality of trench isolation rings disposed concentrically, and
wherein each of the trench isolation rings is coupled in parallel with the other trench isolation rings.

8. The semiconductor device according to claim 5,
wherein the insulating layer in the trench includes an oxide layer disposed on a sidewall of the trench and a high dielectric constant layer disposed a surface on the oxide layer and having a higher dielectric constant than the oxide layer, and
wherein the trench is filled with the oxide layer and the high dielectric constant layer.

9. The semiconductor device according to claim 5, further comprising a contact region,
wherein the insulating layer in the trench includes an oxide layer disposed on two sidewalls of the trench and a polysilicon layer disposed on a surface of the oxide layer,
wherein the trench is filled with the oxide layer and the polysilicon layer,
wherein the contact region is disposed a surface of the polysilicon layer,
wherein the guard ring terminal fixation line includes a pathway that passes through the contact region, and
wherein the bypass capacitor includes two capacitors formed of the oxide layer disposed on the two sidewalls of the trench.

10. The semiconductor device according to claim 5,
wherein the trench isolation structure has one of a quadrangular shape, an octagonal shape, and a circular shape in a plane parallel to the semiconductor substrate.

11. The semiconductor device according to claim 1,
wherein the bypass capacitor includes one of a polysilicon capacitor and a metal capacitor disposed on a surface of the semiconductor substrate,
wherein the polysilicon capacitor includes a stacking structure in which an insulating layer is disposed between polysilicon layers, and
wherein the metal capacitor includes a stacking structure in which an insulating layer is disposed between metal layers.

12. The semiconductor device according to claim 11,
wherein the insulating layer includes a high dielectric constant layer having a higher dielectric constant than an oxide layer.

13. The semiconductor device according to claim 1, further comprising one or more semiconductor elements and one or more bypass capacitors,
wherein each of the bypass capacitors is provided for a corresponding one of the semiconductor elements.

14. The semiconductor device according to claim 1,
wherein the resistor includes at least one of a wiring resistor, a thin film resistor, and a diffused resistor.

15. The semiconductor device according to claim 3,
wherein the guard ring extends to a position deeper than the well.

16. The semiconductor device according to claim 1, further comprising a dielectric isolation region and a well of a first conductivity type,
wherein the semiconductor substrate is a silicon-on-insulator substrate including a support substrate, a buried oxide layer disposed on the support substrate, and a semiconductor layer of a second conductivity type disposed on the buried oxide layer,
wherein the well is disposed in an element region in the semiconductor layer surrounded by the dielectric isolation region,
wherein the semiconductor element is disposed in the well,
wherein the guard ring has a higher conductivity than the semiconductor layer and surrounds at least a part of a periphery of the well, and
wherein a potential of the guard ring terminal is fixed to a potential between the resistor and the bypass capacitor.

17. The semiconductor device according to claim 1, further comprising a well of a first conductivity type,
wherein the semiconductor substrate includes a substrate of the first conductivity type and a semiconductor layer of a second conductivity type disposed on the substrate,
wherein the well is disposed in the semiconductor layer,
wherein the semiconductor element is disposed in the well,
wherein the guard ring has a higher conductivity than the semiconductor layer and surrounds at least a part of a periphery of the well, and
wherein a potential of the guard ring terminal is fixed to a potential between the resistor and the bypass capacitor.
